(19) United States
(12) Patent Application Publication
(10) Pub. No.: US 2025/0374652 A1
(43) Pub. Date: Dec. 4, 2025

(54) SEMICONDUCTOR STRUCTURES WITH REDUCED PARASITIC CAPACITANCE

(71) Applicant: Taiwan Semiconductor Manufacturing Company, Ltd., Hsinchu (TW)

(72) Inventors: Bwo-Ning CHEN, Keelung City (TW); Chang-Miao LIU, Hsinchu City (TW)

(21) Appl. No.: 18/680,530

(22) Filed: May 31, 2024

(51) Int. Cl. H01L 21/8238; H01L 21/285; H01L 27/092; H01L 29/06; H01L 29/08; H01L 29/417; H01L 29/423; H01L 29/66; H01L 29/775; H01L 29/786

(52) U.S. Cl. CPC H10D 84/038; H01L 21/28518; H10D 30/014; H10D 30/031; H10D 30/43; H10D 30/6729; H10D 30/6735; H10D 30/6757; H10D 62/121; H10D 62/151; H10D 64/017; H10D 84/0167; H10D 84/017; H10D 84/0186; H10D 84/85

(57) ABSTRACT

In an embodiment, an exemplary method includes forming a dielectric structure over a substrate, the dielectric structure includes a first portion disposed between a first source/drain feature and a second source/drain feature adjacent to the first source/drain feature and a second portion over the first portion. The exemplary method also includes replacing a part of the first portion of the dielectric structure with a dielectric feature having a different composition than the dielectric structure, and replacing a part of the second portion of the dielectric structure with a source/drain contact electrically coupled to both the first and second source/drain features.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

As integrated circuit (IC) technologies progress towards smaller technology nodes, parasitic capacitance associated with source/drain contacts may have serious bearings on the overall performance of an IC device. While existing source/drain contacts are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure, according to one or more aspects of the present disclosure.

FIG. 2 illustrates a fragmentary top view of an exemplary structure to undergo various stages of operations in the method of FIG. 1, according to various aspects of the present disclosure.

FIGS. 3A, 4A, 5A, 6A, 7A, 8A, 9A, 10A, 11A, 12A, 13A, 14A, 15A, 16A, and 17A (FIGS. 3A-17A) illustrate fragmentary cross-sectional views of the structure taken along line A-A′ as shown in FIG. 2 during various fabrication stages in the method of FIG. 1, according to one or more aspects of the present disclosure.

FIGS. 3B, 4B, 5B, 6B, 7B, 8B, 9B, 10B, 11B, 12B, 13B, 14B, 15B, 16B, and 17B (FIGS. 3B-17B) illustrate fragmentary cross-sectional views of the structure taken along line B-B′ as shown in FIG. 2 during various fabrication stages in the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

As integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A gate-all-around (GAA) transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

The present disclosure provides a method for reducing parasitic capacitance between source/drain contact and its adjacent source/drain feature(s). In an exemplary method, after forming a source/drain contact opening, a lower portion of the source/drain opening is refilled with a dielectric structure, and a source/drain contact is then formed on the dielectric structure and in the source/drain contact opening. Forming the dielectric structure in the source/drain contact opening reduces the depth of the source/drain contact and reduces area of overlap of the source/drain contact and its adjacent source/drain feature(s). Thus, parasitic capacitance of the semiconductor structure may be reduced, and performance of the semiconductor structure may be improved.

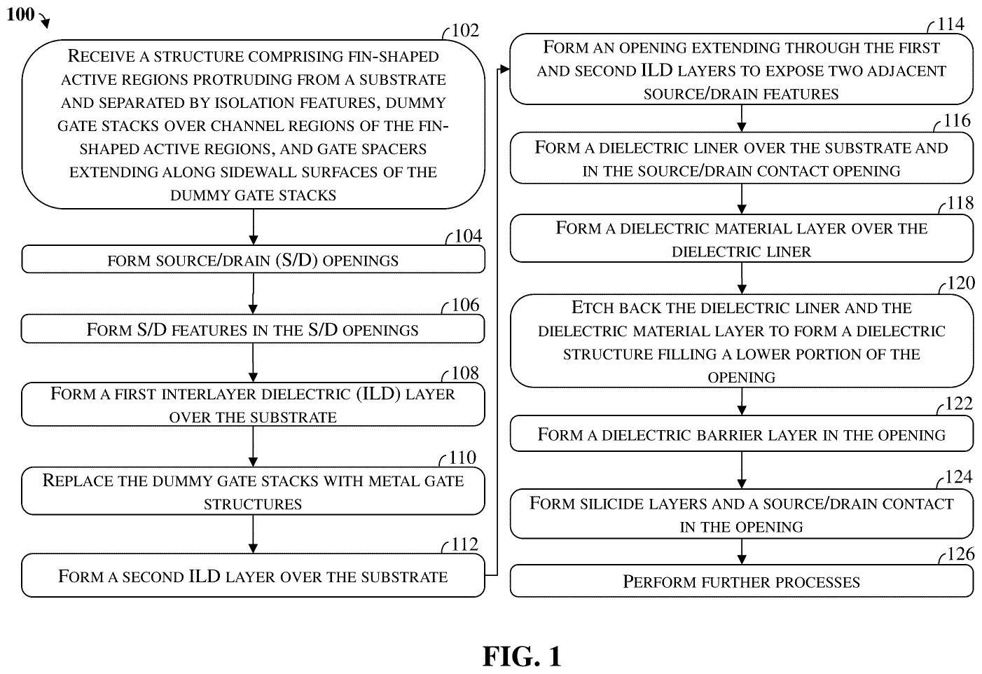

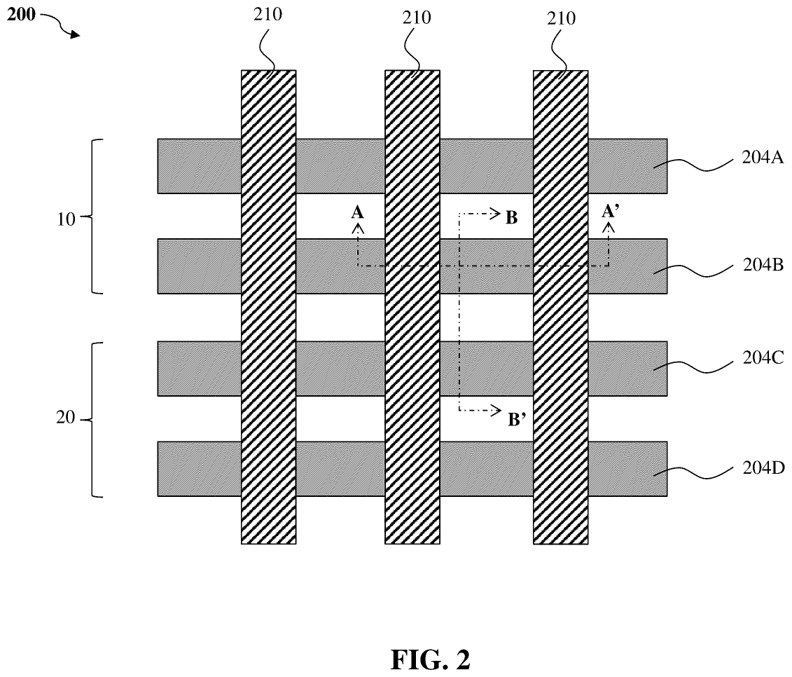

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2, 3A-17A and 3B-17B which are fragmentary top/cross-sectional views of a structure 200 at different stages of fabrication according to embodiments of method 100. Method 100 is merely an example and is not intended to limit the present disclosure to what is explicitly illustrated therein. Additional steps may be provided before, during and after the method 100, and some steps described can be replaced, eliminated, or moved around for additional embodiments of the method. Not all steps are described herein in detail for reasons of simplicity. For avoidance of doubts, the X, Y and Z directions in FIGS. 2 and 3A-17B are perpendicular to one another and are used consistently throughout the present disclosure. Throughout the present disclosure, like reference numerals denote like features unless otherwise excepted.

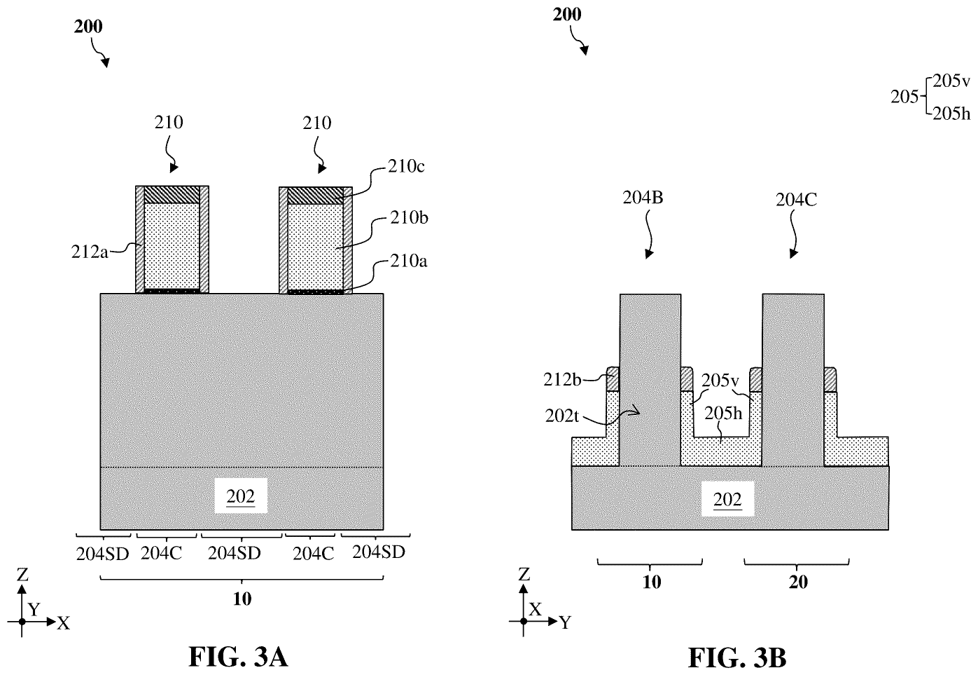

Referring to FIGS. 1, 2, and 3A-3B, method 100 includes a block 102 where a structure 200 that includes a first region 10 and a second region 20 is received. FIG. 2 depicts a fragmentary top view of the structure 200 to undergo various stages of operations in the method of FIG. 1, according to various aspects of the present disclosure. FIG. 3A illustrates a fragmentary cross-sectional view of the structure 200 taken along line A-A′ as shown in FIG. 2, and FIG. 3B illustrates a fragmentary cross-sectional view of the structure 200 taken along line B-B′ as shown in FIG. 2. As illustrated in FIGS. 3A-3B, the structure 200 includes a substrate 202. The substrate 202 may be an elementary (single element) semiconductor, such as silicon (Si) or germanium (Ge) in a crystalline structure; a compound semiconductor, such as silicon carbide (SiC), gallium arsenic (GaAs), gallium phosphide (GaP), indium phosphide (InP), indium arsenide (InAs), and/or indium antimonide (InSb); an alloy semiconductor such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP). In one embodiment, the substrate 202 is a silicon (Si) substrate. The substrate 202 may be uniform in composition or may include various layers, some of which may be selectively etched to form fin-shaped active regions (e.g., the fin-shaped active regions 204A-204D). The layers may have similar or different compositions, and in various embodiments, some substrate layers have non-uniform compositions to induce device strain and thereby tune device performance. Examples of layered substrates include silicon-on-insulator (SOI) substrates 202. In some such examples, a layer of the substrate 202 may include an insulator such as a semiconductor oxide, a semiconductor nitride, a semiconductor oxynitride, a semiconductor carbide, and/or other suitable insulator materials. Doped regions, such as wells, may be formed in the substrate 202. In the embodiments represented by FIG. 2, a portion of the substrate 202 in the first region 10 is doped with an n-type dopant and may be referred to as an n-type well (not shown), and a portion of the substrate 202 in the second region 20 is doped with a p-type dopant and may be referred to as a p-type well (not shown). The n-type dopant may include phosphorus (P) or arsenic (As). The p-type dopant may include boron (B), boron difluoride (BF₂), or indium (In). The n-type well and the p-type well may be formed using ion implantation or thermal diffusion and may be considered portions of the substrate 202. As will be described further below, the first region 10 is p-type field effect transistor (PFET) region for forming PFET(s) and the second region 20 is an n-type field effect transistor (NFET) region for forming NFET(s).

Still referring to FIGS. 2 and 3A-3B, the structure 200 includes a number of fin-shaped active regions (e.g., fin-shaped active regions 204A, 204B, 204C, 204D) protruding from the substrate 202. In the illustrated embodiment, the first region 10 includes a fin-shaped active region 204A and a fin-shaped active region 204B extending vertically from the substrate 202, and the second region 20 includes a fin-shaped active region 204C and a fin-shaped active region 204D extending vertically from the substrate 202. The number of fin-shaped active regions depicted in FIGS. 2 and 3A-3B is just an example, the structure 200 may include any suitable number of fin-shaped active regions. Each of the fin-shaped active regions 204A-204D extends lengthwise along the X direction and is divided into channel regions 204C overlapped by dummy gate stacks 210 (to be described below) and source/drain regions 204SD not overlapped by the dummy gate stacks 210. Source/drain region(s) 204SD may refer to a source region or a drain region, individually or collectively dependent upon the context. Each of the channel regions 204C is disposed between two source/drain regions 204SD along the X direction.

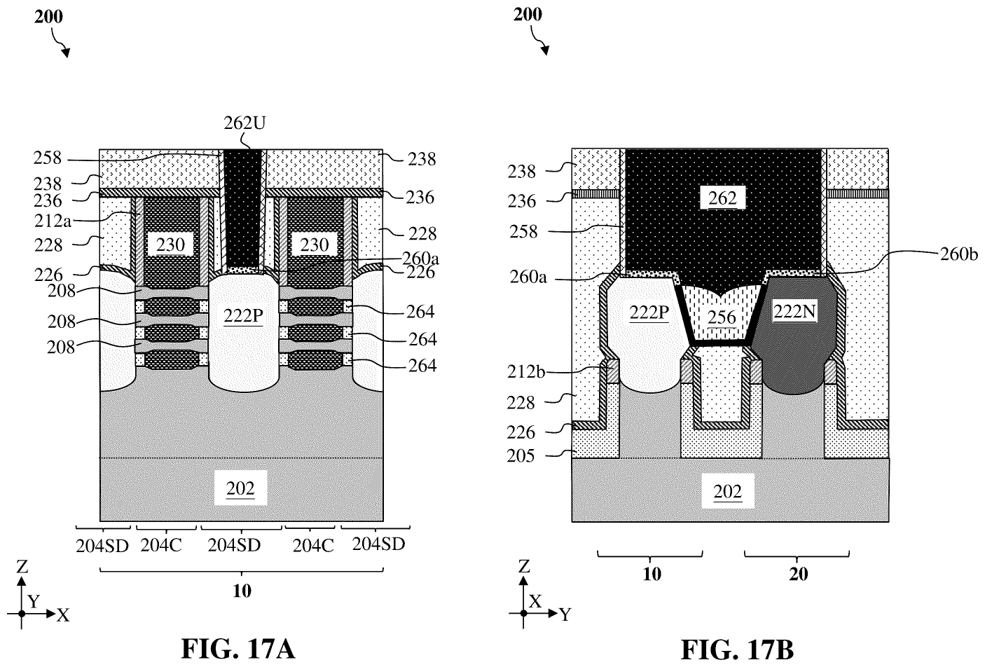

For embodiments in which the structure 200 will be fabricated to include FinFETs, each of the fin-shaped active regions 204A-204D may be formed from a top portion 202t (shown in FIG. 3B) of the substrate 202. For embodiments in which the structure 200 will be fabricated to include GAA transistors, each of the fin-shaped active regions 204A-204D may include a vertical stack (not shown) of alternating semiconductor layers and a portion of the substrate 202. The vertical stack includes a number of channel layers 208 (shown in FIG. 17A) interleaved by a number of sacrificial layers (not shown). Each of the channel layers 208 may include a semiconductor material such as, silicon, germanium, silicon carbide, silicon germanium, GeSn, SiGeSn, SiGeCSn, other suitable semiconductor materials, or combinations thereof, while each sacrificial layer has a composition different from that of the channel layers 208. In an embodiment, each of the channel layers 208 includes silicon (Si), each of the sacrificial layers includes silicon germanium (SiGe).

The structure 200 also includes isolation features 205 formed around the fin-shaped active regions to isolate two adjacent fin-shaped active regions. The isolation features 205 may include shallow trench isolation (STI) features 205. In an example process, a dielectric material for the isolation features 205 is first deposited over the structure 200 to fill the trenches between the fin-shaped active regions 204A-204D. In some embodiments, the dielectric material may include silicon oxide, silicon oxynitride, fluorine-doped silicate glass (FSG), a low-k dielectric, combinations thereof, and/or other suitable materials. In various examples, the dielectric material may be deposited by a CVD process, a flowable CVD (FCVD) process, spin-on coating, and/or other suitable process. The deposited dielectric material is then thinned and planarized, for example by a chemical mechanical polishing (CMP) process, until top surfaces of the fin-shaped active regions 204A-204D are exposed. The planarized dielectric material is further recessed or etched back by a dry etching process, a wet etching process, and/or a combination thereof to form the STI features 205. Upper portions of the fin-shaped active regions 204A-204D rise above the STI features 205 while lower portions of the fin-shaped active regions 204A-204D remain covered or buried in the STI features 205. The deposited dielectric material may be a single-layer structure or a multi-layer structure. In the present embodiments, at least one of the STI features 205 includes a horizontal portion 205h extending between two adjacent fin-shaped active regions (e.g., the fin-shaped active regions 204B and 204C) and two vertical portions 205v extending along bottom sidewall surfaces of the two adjacent fin-shaped active regions.

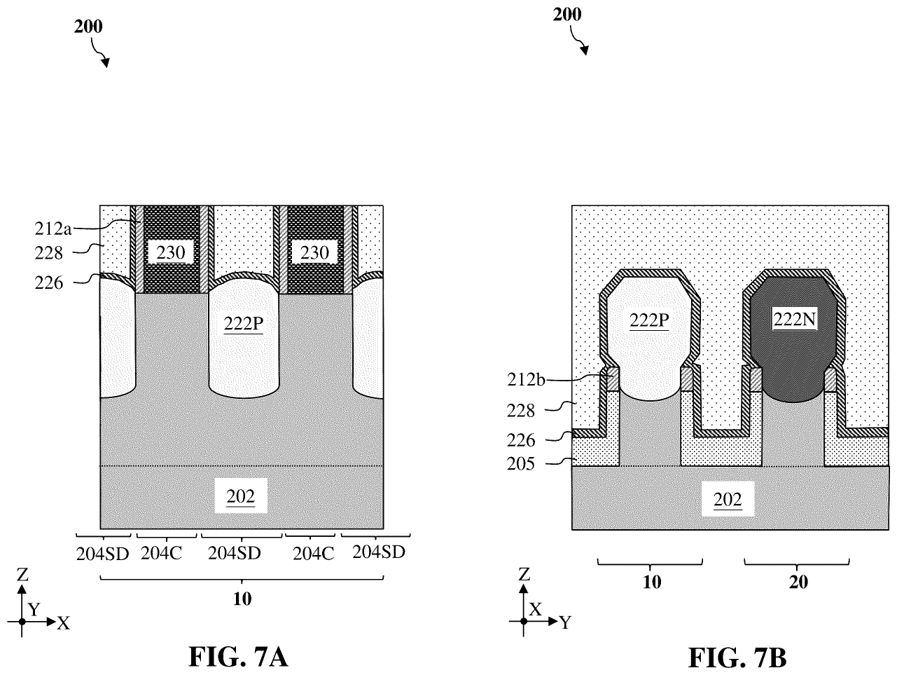

The structure 200 also includes dummy gate stacks 210. Each of the dummy gate stacks 210 includes a dummy gate dielectric layer 210a, a dummy gate electrode layer 210b over the dummy gate dielectric layer 210a, and a gate-top hard mask layer 210c over the dummy gate electrode layer 210b. The dummy gate dielectric layer 210a may include silicon oxide. The dummy gate electrode layer 210b may include polysilicon. The gate-top hard mask layer 210c may include silicon oxide, silicon nitride, and/or other suitable materials. Suitable deposition process, photolithography and etching process may be employed to form the dummy gate stacks 210. In this embodiment, a gate replacement process (or gate-last process) is adopted where the dummy gate stacks 210 serve as placeholders for functional gate structures (e.g., gate structures 230 shown in FIGS. 7A-7B). Other processes and configurations are possible. Three dummy gate stacks 210 are shown in FIG. 2, but the structure 200 may include any suitable number of dummy gate stacks 210.

The structure 200 also includes gate spacers 212a extending along sidewall surfaces of the dummy gate stacks 210. Each of the gate spacers 212a may be a single-layer structure or a multi-layer structure. In an example process, a spacer layer is conformally deposited over the structure 200 by atomic layer deposition (ALD), chemical vapor deposition (CVD), or any other suitable deposition process. The term “conformally” may be used herein for ease of description of a layer having substantially uniform thickness over various regions of the structure 200. The spacer layer may include silicon oxide, silicon nitride, silicon oxycarbide, silicon oxycarbonitride, silicon carbonitride, metal nitride, other suitable dielectric materials, or combinations thereof. An etching process is performed to remove portions of the spacer layer over top-facing surfaces of the structure 200 to form gate spacers 212a extending along sidewalls of the dummy gate stacks 210. The deposition and etching of the spacer layer also forms fin sidewall spacers 212b (shown in FIG. 3B) extending along lower portions of sidewalls of the fin-shaped active regions 204A-204D and disposed on the vertical portions 205v of the STI features 205.

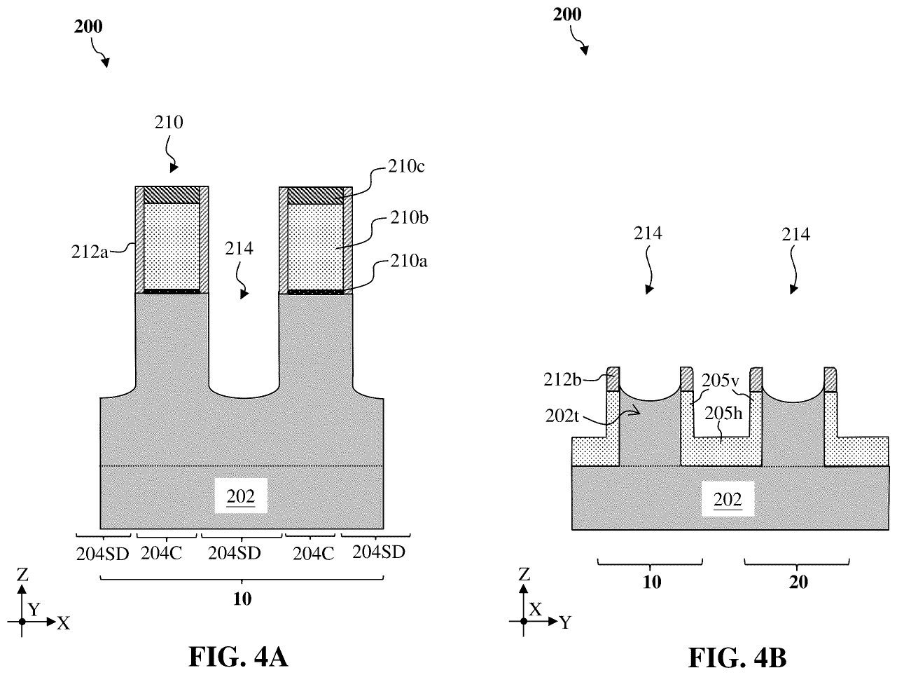

Referring to FIGS. 1 and 4A-4B, method 100 includes a block 104 where source/drain openings 214 are formed. The source/drain regions 204SD of the fin-shaped active regions 204A-204D are recessed to form source/drain openings 214. In some embodiments, the source/drain regions 204SD of the fin-shaped active regions 204A-204D are anisotropically etched by a plasma etch with a suitable etchant, such as fluorine-containing etchant, oxygen-containing etchant, hydrogen-containing etchant, a fluorine-containing etchant (e.g., CF₄, SF₆, CH₂F₂, CHF₃, and/or C₂F₆), a chlorine-containing etchant (e.g., Cl₂, CHCl₃, CCl₄, and/or BCl₃), a bromine-containing etchant (e.g., HBr and/or CHBr₃), an iodine-containing etchant, other suitable etchants, and/or combinations thereof.

For embodiments in which the structure 200 will be fabricated to include GAA transistors, after forming the source/drain openings 214, the sacrificial layers of the vertical stack will be selectively and laterally etched to form inner spacer recesses. Inner spacer features 264 (shown in FIG. 17A) are then formed in the inner spacer recesses. The inner spacer features may include any suitable dielectric material SiN, SiO and/or SiO₂, SiCN, SiOC, SiON, SiOCN, a low-k dielectric material, other suitable dielectric material, or combination thereof. The inner spacer features 264 may each be configured as a single-layer structure or a multi-layer structure including a combination of the dielectric materials provided herein. In some embodiments, the inner spacer features 264 have a different composition from that of the gate spacers 212a.

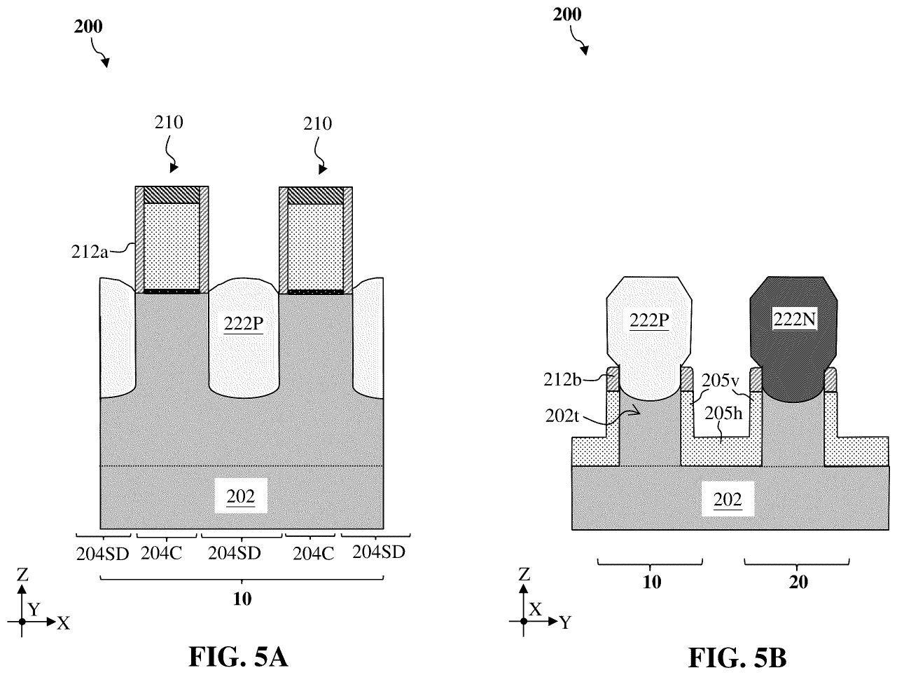

Referring now to FIGS. 1 and 5A-5D, method 100 includes a block 106 where source/drain features (e.g., 222P and 222N) are formed in the source/drain openings 214. In this illustrated embodiment, source/drain features 222P and 222N are formed in the source/drain openings 214 in the first region 10 and the second region 20, respectively. Source/drain feature(s) may refer to a source or a drain, individually or collectively dependent upon the context. The source/drain features 222P are coupled to the channel regions 204C in the first region 10. The source/drain features 222N are coupled to the channel regions 204C in the second region 20. The source/drain features 222N and 222P each may be epitaxially and selectively formed from exposed sidewalls of the channel layers 208 by using an epitaxial process, such as vapor phase epitaxy (VPE), ultrahigh vacuum chemical vapor deposition (UHV-CVD), molecular-beam epitaxy (MBE), and/or other suitable processes.

Example N-type source/drain features 222N may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process. Example P-type source/drain features 222P may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. In some embodiments, each of the N-type source/drain features 222N and the P-type source/drain features 222P may include multiple semiconductor layers with different doping concentrations. The N-type source/drain features 222N and the P-type source/drain features 222P may be formed in any suitable sequential orders.

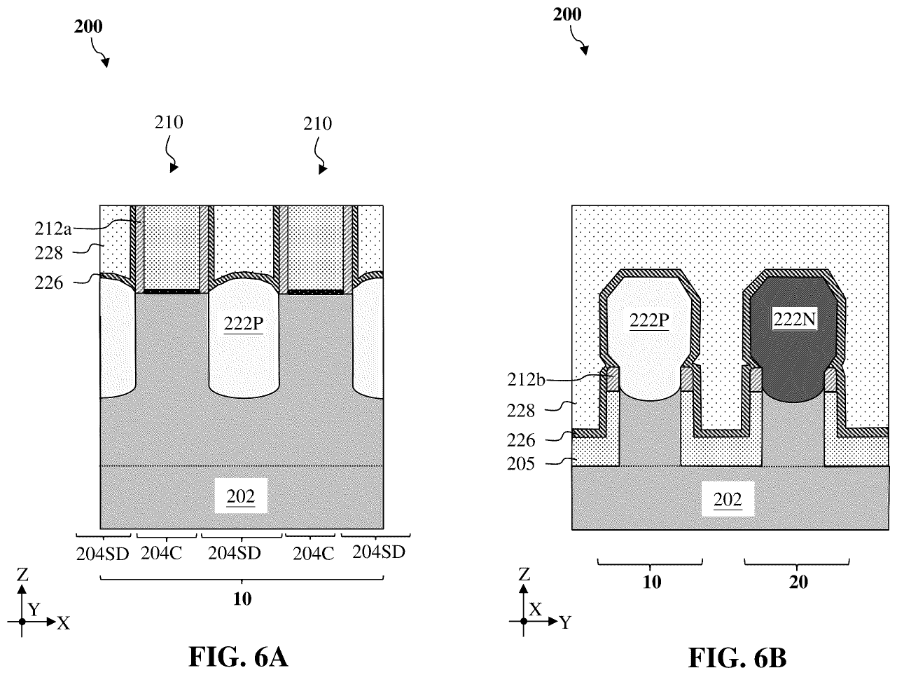

Referring now to FIGS. 1 and 6A-6B, method 100 includes a block 108 where a first interlayer dielectric (ILD) layer 228 is formed over the substrate 202. A contact etch stop layer (CESL) 226 and the first interlayer dielectric (ILD) layer 228 are deposited over the structure 200. The CESL 226 may include silicon nitride, silicon oxynitride, and/or other suitable materials and may be formed by ALD, plasma-enhanced chemical vapor deposition (PECVD) process and/or other suitable deposition or oxidation processes. The first ILD layer 228 is deposited by a PECVD process or other suitable deposition technique over the structure 200 after the deposition of the CESL 226. The first ILD layer 228 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A planarization process, such a chemical mechanical polishing (CMP) process may be performed to the structure 200 to remove excess materials and expose top surfaces of the dummy gate electrode layers 210b in the dummy gate stacks 210.

Referring now to FIGS. 1 and 7A-7B, method 100 includes a block 110 where the dummy gate stacks 210 are replaced by metal gate structures 230. After exposing the top surfaces of the dummy gate electrode layers 210b in the dummy gate stacks 210, an etching process is implemented to selectively remove the dummy gate electrode layers 212 and the dummy gate dielectric layers 211 of the dummy gate stacks 210 without substantially removing the gate spacers 212a to form gate trenches. Metal gate structures 230 are then formed in the gate trenches in the first region 10 and the second region 20. The formation of the metal gate structure 230 includes forming an interfacial layer over the substrate 202. The interfacial layer may include silicon oxide or other suitable material and may be formed using a suitable method, such as atomic layer deposition (ALD), chemical vapor deposition (CVD), thermal oxidation, or other suitable method. In an embodiment, the interfacial layer is formed by thermal oxidation. After forming the interfacial layer, a dielectric layer is formed over the structure 200 and in the gate trenches. In an embodiment, the dielectric layer is deposited conformally over the structure 200. The term “conformally” may be used herein for ease of description of a layer having a substantially uniform thickness over various regions. In some embodiments, the dielectric layer is high-k dielectric layer as its dielectric constant is greater than that of silicon dioxide (˜3.9). In some implementations, the dielectric layer may include titanium oxide (TiO₂), tantalum oxide (Ta₂O₅), hafnium silicon oxide (HfSiO₄), zirconium oxide (ZrO₂), zirconium silicon oxide (ZrSiO₂), aluminum oxide (Al₂O₃), zirconium oxide (ZrO), yttrium oxide (Y₂O₃), SrTiO₃ (STO), BaTiO₃ (BTO), BaZrO, aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The dielectric layer and the interfacial layer may be collectively referred to as a gate dielectric layer.

The formation of the metal gate structure 230 also includes forming a gate electrode over the gate dielectric layer. The gate electrode may be a multi-layer structure that includes at least one work function layer and a metal fill layer. By way of example, the at least one work function layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), or tantalum carbide (TaC). The metal gate structure 230 formed in the first region 10 may include at least a P-type work function layer. The metal gate structure 230 formed in the second region 20 may include at least an N-type work function layer. The metal fill layer may include aluminum (Al), tungsten (W), nickel (Ni), titanium (Ti), ruthenium (Ru), cobalt (Co), platinum (Pt), tantalum silicon nitride (TaSiN), copper (Cu), other refractory metals, or other suitable metal materials or a combination thereof. In various embodiments, the gate electrode may be formed by atomic layer deposition (ALD), physical vapor deposition (PVD), chemical vapor deposition (CVD), e-beam evaporation, or other suitable process. In various embodiments, a planarization process, such as a chemical mechanical polishing (CMP) process, may be performed to remove excess materials over the first ILD layer 228 to provide a substantially planar top surface and facilitate the performing of further processes.

For embodiments in which the structure 200 will be fabricated to form GAA transistors, before forming the metal gate structures 230, method 100 further removes the sacrificial layers from the vertical stack during a sheet (or wire) formation process, thereby forming openings (not depicted) between the channel layers 208 (shown in FIG. 17). In the present embodiments, the sheet formation process selectively removes the sacrificial layers without removing, or substantially removing, the channel layers 208. The metal gate structures 230 are further configured to wrap around the channel layers 208.

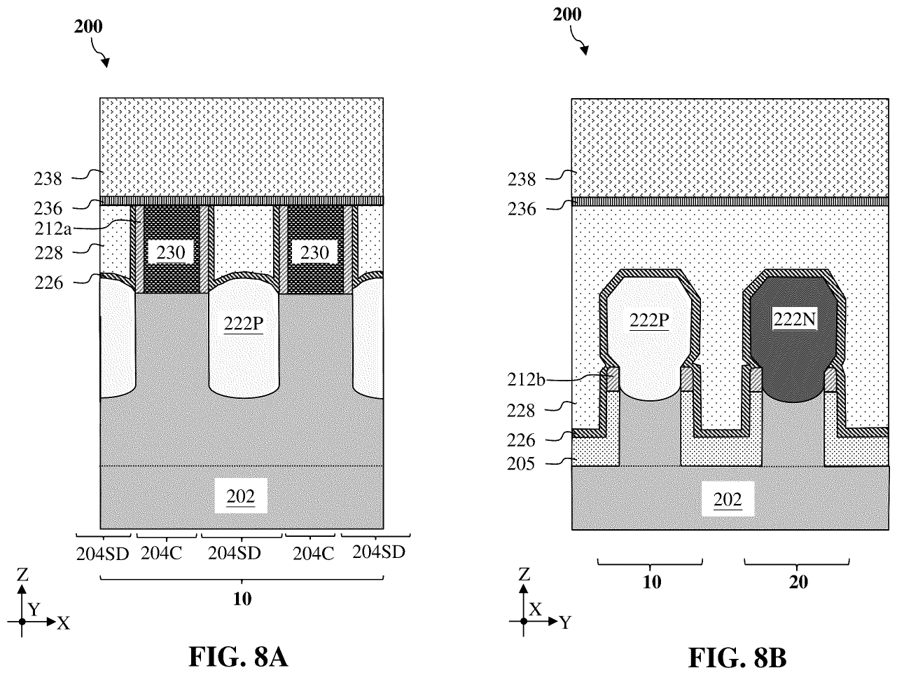

Referring now to FIGS. 1 and 8A-8B, method 100 includes a block 112 where a second interlayer dielectric (ILD) layer 238 is formed over the substrate 202. After forming the metal gate structures 230, an etch stop layer 236 is formed over the first interlayer dielectric (ILD) layer 228. The etch stop layer 236 may include silicon nitride, silicon oxynitride, and/or other suitable materials and may be formed by ALD, plasma-enhanced chemical vapor deposition (PECVD) process and/or other suitable deposition or oxidation processes. The formation of the etch stop layer 236 may facilitate the formation of gate vias over the metal gate structures 230 during subsequent fabrication process. The second ILD layer 238 is deposited over the etch stop layer 236 by a PECVD process or other suitable deposition technique over the structure 200. The second ILD layer 238 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

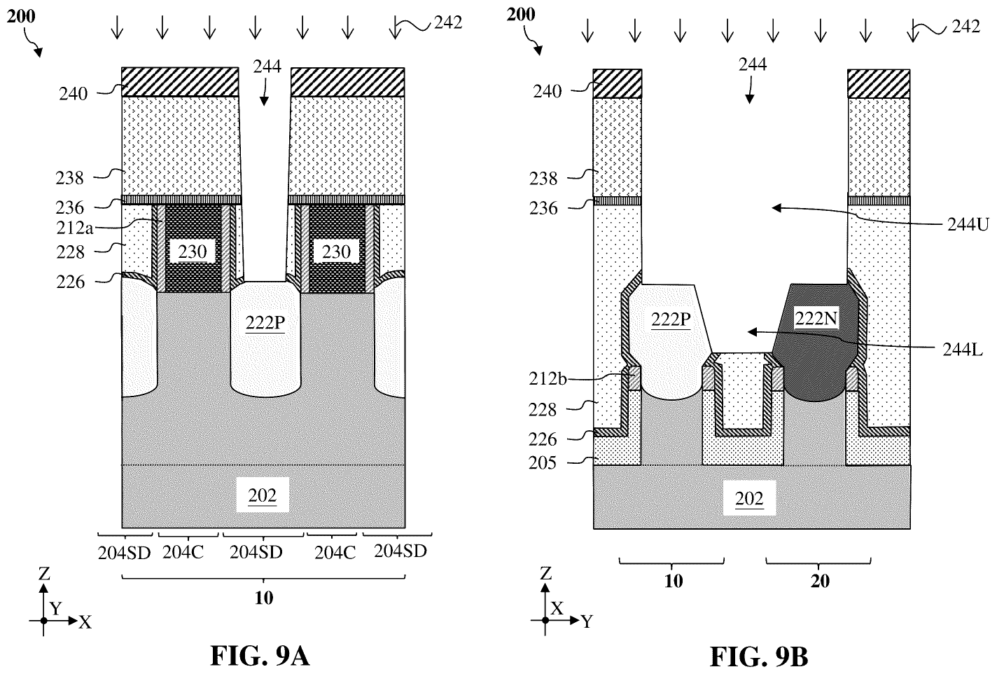

Referring now to FIGS. 1 and 9A-9B, method 100 includes a block 114 where an opening 244 is formed to expose the source/drain features 222P and 222N. In this illustrated embodiments, a patterned mask 240 is formed over the structure 200. The patterned mask 240 may include silicon nitride, silicon oxynitride, silicon carbonitride, or other suitable dielectric material. In an exemplary process for forming the patterned mask 240, a hard mask layer may be deposited using chemical vapor deposition (CVD), atomic layer deposition (ALD), or other suitable deposition technique. A photoresist layer may be then deposited over the hard mask layer using spin-on coating, CVD, or other similar processes. The photoresist layer is baked in a pre-exposure baking process, exposed to a radiation source reflected from or transmitting through a photomask with pattern, baked in a post-exposure baking process and developed in a developing process. Because the photoresist layer is selected to be sensitive to the radiation, exposed (or non-exposed) portions of the photoresist layer undergo chemical changes to become soluble in a developer solution during a subsequent developing process. The patterned photoresist layer carries pattern that corresponds to the pattern of the photomask. While using the patterned photoresist layer as an etch mask, the hard mask layer is etched to form the patterned mask 240. In this illustrated embodiment, the patterned mask 240 includes an opening disposed directly over the source/drain feature 222P, the source/drain feature 222N, and a portion of the dielectric layers disposed laterally between the source/drain feature 222P and the source/drain feature 222N.

While using the patterned mask 240 as an etch mask, an etching process 242 is performed to remove portions of the dielectric layers (e.g., CESL 226, first ILD layer 228, etch step layer 236, and second ILD layer 238) to form an opening 244. The etching process 242 may be a dry etch process that includes use of argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, or combinations thereof. The opening 244 exposes the source/drain feature 222P and the source/drain feature 222N. In this illustrated embodiment, top surfaces and sidewall surfaces of the source/drain feature 222P and the source/drain feature 222N are at least partially exposed. In other words, the etching process 242 not only removes a portion of the dielectric layers (e.g., CESL 226, first ILD layer 228, etch step layer 236, and second ILD layer 238) disposed over the source/drain feature 222P and the source/drain feature 222N, but also removes a portion of the dielectric layers (e.g., CESL 226, first ILD layer 228) disposed between the source/drain feature 222P and the source/drain feature 222N. The etching process 242 may etch the first and second ILD layers 228 and 238 faster than it etches the CESL 226 and the etch stop layer 236. As a result, as illustrated by FIG. 9B, upon completion of the etching process 242, the opening 244 includes a lower portion 244L disposed laterally between the source/drain features 222P and 222N and extending from a sidewall of the source/drain feature 222P to a sidewall of the source/drain feature 222N. The lower portion 244L is disposed directly over the STI feature 205 and exposes the top surface of the first ILD layer 228 and the CESL 226 on the STI feature 205. The opening 244 also includes an upper portion 244U exposing a top surface of the source/drain feature 222P and a top surface of the source/drain feature 222N.

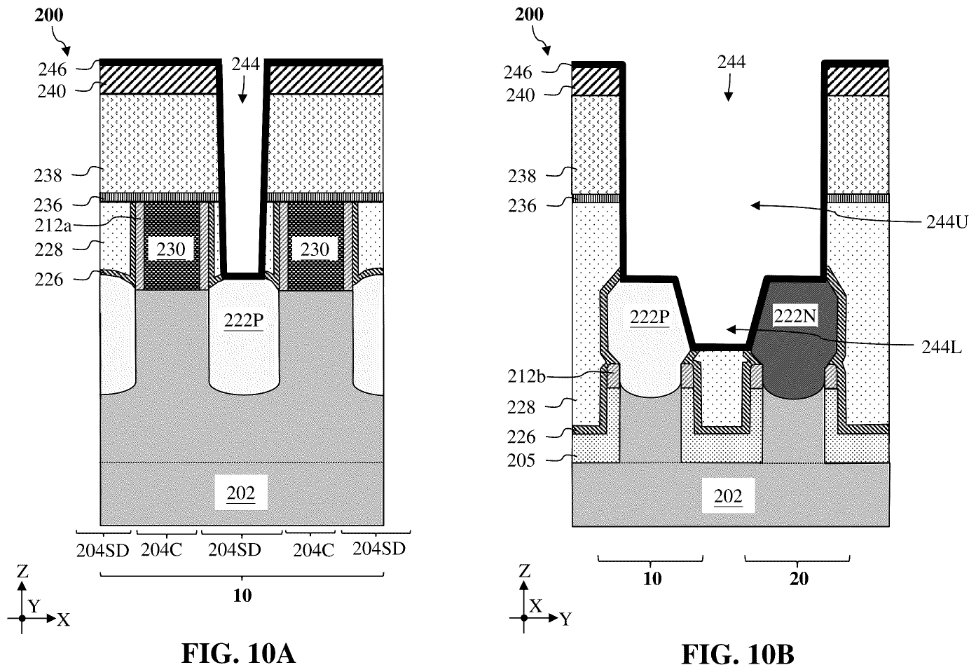

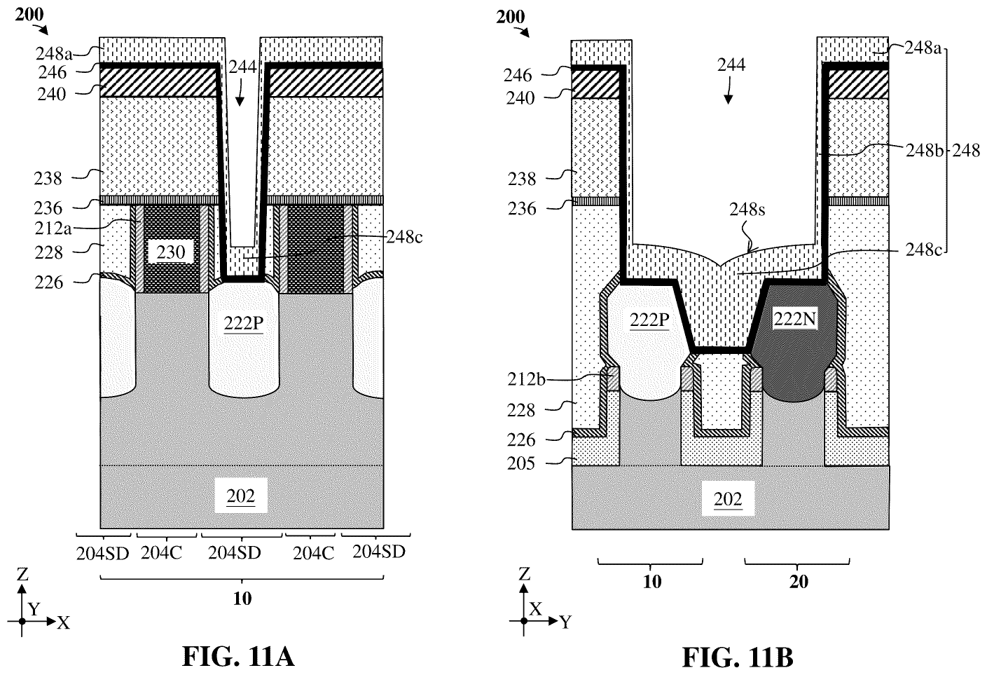

Referring now to FIGS. 1 and 10A-10B, method 100 includes a block 116 where a dielectric liner 246 is formed over the substrate 202 and in the opening 244. In an embodiment, the dielectric liner 246 is conformally deposited to have a generally uniform thickness over the top surface of the structure 200 (e.g., having substantially the same thickness on top surfaces and sidewall surfaces of the structure 200) and partially fills the opening 244. In this illustrated embodiment, the dielectric liner 246 extends along exposed surfaces of the source/drain feature 222P and source/drain feature 222N and top surfaces of the portions of the CESL 226 and first ILD layer 228 disposed directly on the STI feature 205. The dielectric liner 246 may be formed by performing a deposition process such as a CVD process, a PECVD process, an ALD process, or other suitable deposition process. In the present embodiments, the dielectric liner 246 is selected to have a composition different from that of the source/drain features 222N and 222P, the CESL 226, the first ILD layer 228, the etch step layer 236, and the second ILD layer 238 and a dielectric material layer 248 (shown in FIGS. 11A-11B) to ensure that the dielectric liner 246 possesses etch selectivity with respect to these material layers. In an embodiment, the dielectric liner 246 may include silicon oxycarbide (SiOC). In another embodiment, the dielectric liner 246 may include silicon oxycarbonitride (SiOCN).

Referring now to FIGS. 1 and 11A-11B, method 100 includes a block 118 where a dielectric material layer 248 is formed over the substrate 202 to partially fill the opening 244. The dielectric material layer 248 may be deposited by using a chemical vaper deposition (CVD), physical vaper deposition (PVD), or other suitable processes. In an embodiment, the dielectric material layer 248 is deposited by using a physical vaper deposition (PVD) process. Due to the properties of the PVD process, portions of the dielectric material layer 248 formed on a top or planar surface are thicker than a portion of the dielectric material layer 248 formed on a side surface. More specifically, as depicted in FIG. 11B, the dielectric material layer 248 includes a first horizontal portion 248a formed over top surfaces of the patterned mask 240, a vertical portion 248b extending along exposed sidewall surface of the opening 244, and a second horizontal portion 248c formed in the opening 244 and directly over the first ILD layer 228 and the source/drain features 222P and 222N. In an embodiment, a thickness of the second horizontal portion 248c of the dielectric material layer 248 is greater than a thickness of the first horizontal portion 248a of the dielectric material layer 248, and the thickness of the first horizontal portion 248a of the dielectric material layer 248 is greater than a thickness of the vertical portion 248b of the dielectric material layer 248. In an embodiment, a part of the second horizontal portion 248c of the dielectric material layer 248 formed directly over the source/drain feature 222P/222N is thicker than the first horizontal portion 248a of the dielectric material layer 248. In this illustrated embodiment, the second horizontal portion 248c of the dielectric material layer 248 has a top surface 248s that is non-planar. The top surface 248s may curve inward the most at its middle point. More specifically, the top surface 248s is composed of two segments with distinct concave curvatures. The left segment exhibits a concave-down, decreasing profile, while the right segment displays a concave-down, increasing profile. Additionally, the left segment of the top surface 238s interfaces the right segment of the top surface 238s, contributing to the overall unique shape of the top surface 248s.

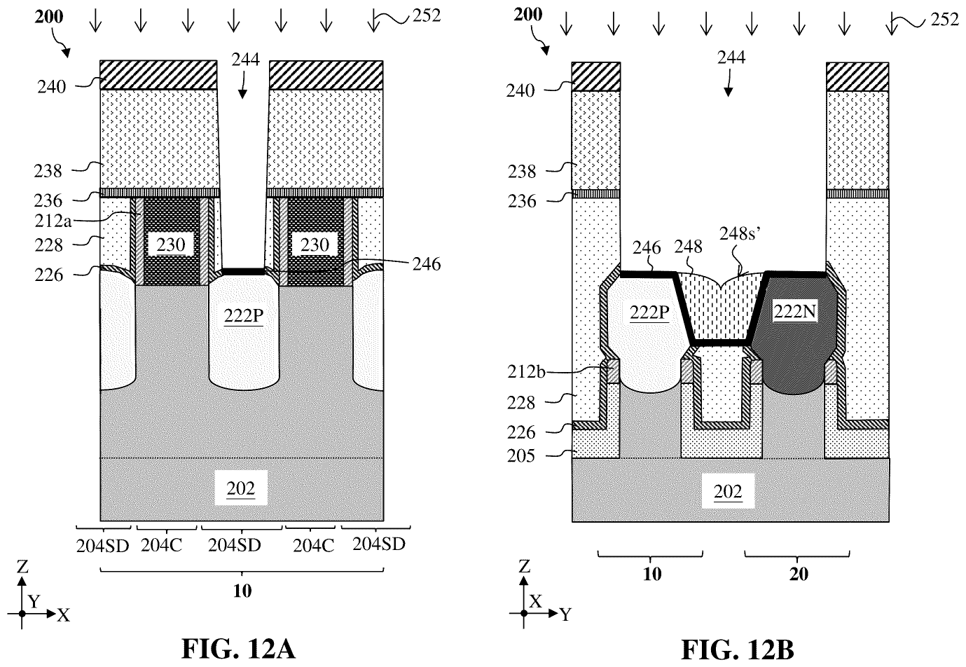

In the present embodiments, the dielectric material layer 248 is selected to have a composition different from that of the source/drain features 222N and 222P and dielectric liner 246 to ensure that the dielectric material layer 248 possesses etch selectivity with respect to these material layers. In an embodiment, the dielectric material layer 248 may include silicon oxycarbide (SiOC). In another embodiment, the dielectric material layer 248 may include silicon oxycarbonitride (SiOCN). For embodiments in which both the dielectric liner 246 and the dielectric material layer 248 include a same material (e.g., SiOC or SiOCN), carbon concentration and/or nitrogen concentration in the dielectric material layer 248 is different than the carbon concentration and/or nitrogen concentration in the dielectric liner 246 such that etchants of subsequent etching process (e.g., step 252 shown in FIG. 12B) would etch the dielectric liner 246 and the dielectric material layer 248 at different etch rates.

Referring now to FIGS. 1, 12A-12B and 13A-13B, method 100 includes a block 120 where the dielectric liner 246 and the dielectric material layer 248 are etched back to form a dielectric structure 256 partially filling the lower portion 244L of the opening 244. In this illustrated embodiment, the formation of the dielectric structure 256 includes implementing an etching process comprising a first step 252 (may be referred to as the “first etching process 252”) and a second step 254 (may be referred to as the “second etching process 254”). With respect to FIGS. 12A-12B, the first step 252 of the etching process selectively etches the dielectric liner 246 and the dielectric material layer 248 without substantially etching the CESL 226, the first ILD layer 228, the etch stop layer 236, and the second ILD layer 238. For example, the first horizontal portion 248a, the vertical portion 248b, and an upper part of the second horizontal portion 248c of the dielectric material layer 248 are removed. The removal of those portions of the dielectric material layer 248 exposes portions of the dielectric liner 246 previously covered by those portions of the dielectric material layer 248. A first horizontal portion and a vertical portion of the dielectric liner 246 covered by the first horizontal portion 248a and the vertical portion 248b of the dielectric material layer 248, respectively, are exposed earlier than a second horizontal portion of the dielectric liner 246 covered by the second horizontal portion 248c of the dielectric material layer 248. In this embodiment, the first step 252 of the etching process also etches the dielectric liner 246 and the dielectric material layer 248 at different rates. More specifically, the first step 252 of the etching process etches the dielectric liner 246 at a rate higher than it etches the dielectric material layer 248, such that at least a portion of the dielectric material layer 248 remains in the lower portion 244L of the opening 244 upon completion of the first step 252 of the etching process. In this illustrated embodiment, due to the thickness relationship of different portions of the dielectric material layer 248 described above and the selection of etchant of the first step 252 of the etching process, upon completion of the first step 252 of the etching process, the recessed dielectric liner 246 covers the top surfaces of the source/drain features 222P and 222N and extends along sidewall and bottom surfaces of the recessed dielectric material layer 248. The recessed dielectric material layer 248 is spaced apart from sidewall surfaces of the source/drain features 222P and 222N by the recessed dielectric liner 246. The recessed dielectric material layer 248 has a top surface 248s′ having a profile substantially similar to the top surface 248s. The top surface 248s′ may be lower than a topmost surface of the recessed dielectric liner 246. The profile of the recessed dielectric liner 246 and the recessed dielectric material layer 248 may be controlled by the duration of the first step 252 of the etching process. Etchant of the first step 252 of the etching process may include a fluorine-containing etchant (e.g., CF₄, SF₆, CH₂F₂, CHF₃, and/or C₂F₆) or other suitable materials.

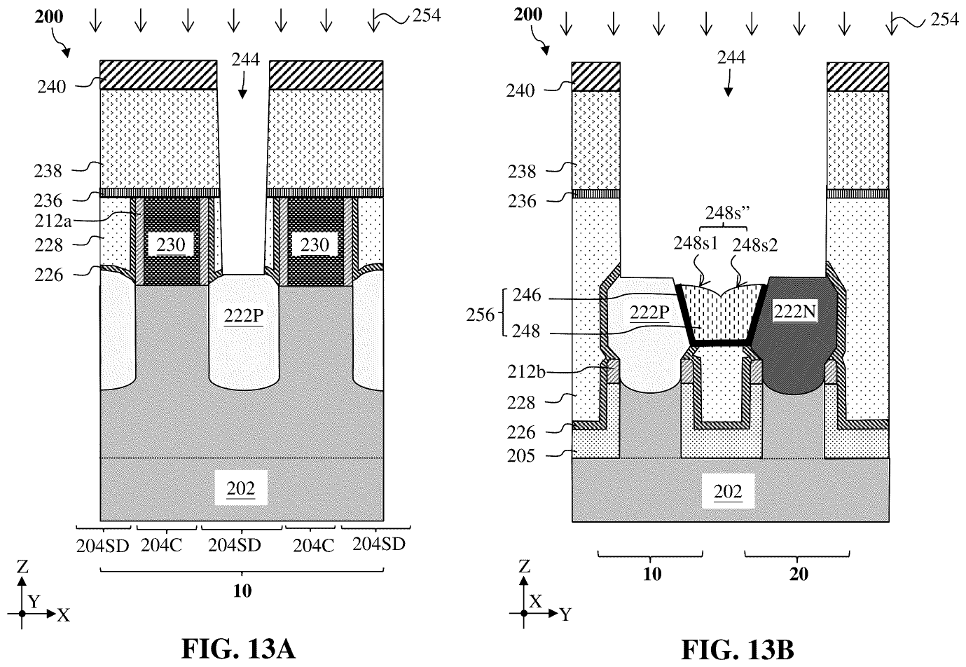

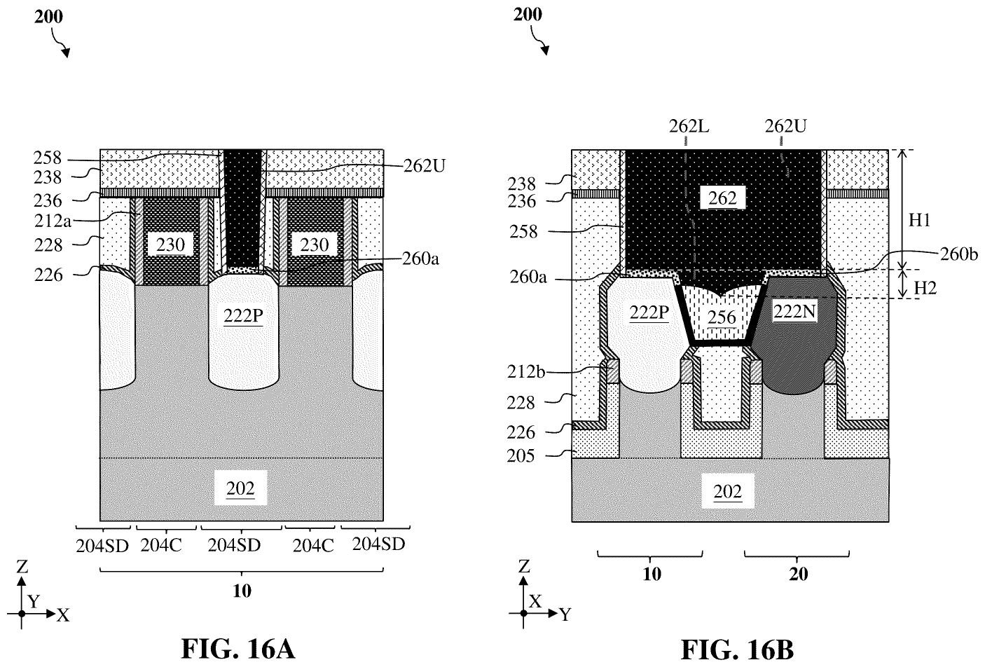

With respect to FIGS. 13A-13B, the second step 254 of the etching process selectively etches the dielectric liner 246 without substantially the source/drain features 222P and 222N. In this embodiment, upon completion of the second step 254 of the etching process, top surfaces and parts of the sidewall surfaces of the source/drain features 222P and 222N are exposed by removing portions of the dielectric liner 246. The second step 254 of the etching process also slightly etches the dielectric material layer 248. The recessed dielectric material layer 248 has a top surface 248s″ having a profile that is substantially similar to the top surface 248s. More specifically, the top surface 248s″ has two segments 248s1 and 248s2 with distinct concave curvatures. The left segment 248s1 exhibits a concave-down, decreasing profile, while the right segment 248s2 displays a concave-down, increasing profile. Additionally, the left segment 248s1 of the top surface 248s″ interfaces the right segment 248s2 of the top surface 248s″, contributing to the overall unique shape of the top surface 248s″. The second step 254 of the etching process for etching the dielectric liner 246 may be a dry etch process that includes use of argon (Ar), a fluorine-containing etchant (for example, SF₆, NF₃, CH₂F₂, CHF₃, C₄F₈, C₂F₆, C₂F, CF₄, CH₂F₂, CHF₃, and/or C₄F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, or combinations thereof. In an embodiment, etchant(s) of the second step 254 of the etching process is different than etchant(s) of the first step 252 of the etching process. Etch rate difference between the dielectric liner 246 and the dielectric material layer 248 during the performing of the second step 254 of the etching process is less than the etch rate difference between the dielectric liner 246 and the dielectric material layer 248 during the performing of the first step 252 of the etching process. The combination of the recessed dielectric liner 246 and the recessed dielectric material layer 248 after the performing of the second step 254 of the etching process may be referred to as the dielectric structure 256. As depicted in FIG. 13B, the dielectric structure 256 at least partially fills the lower portion 244L of the opening 244. Forming this dielectric structure 256 in the lower portion 244L of the opening 244 would reduce a volume of a portion of the source/drain contact 262 (shown in FIGS. 16A-16B) disposed laterally between the source/drain feature 222P and the source/drain feature 222N and thus a depth of the source/drain contact 262. Thus, the resultant semiconductor structure 200 would have a reduced parasitic capacitance compared to semiconductor structures that are free of the dielectric structure 256.

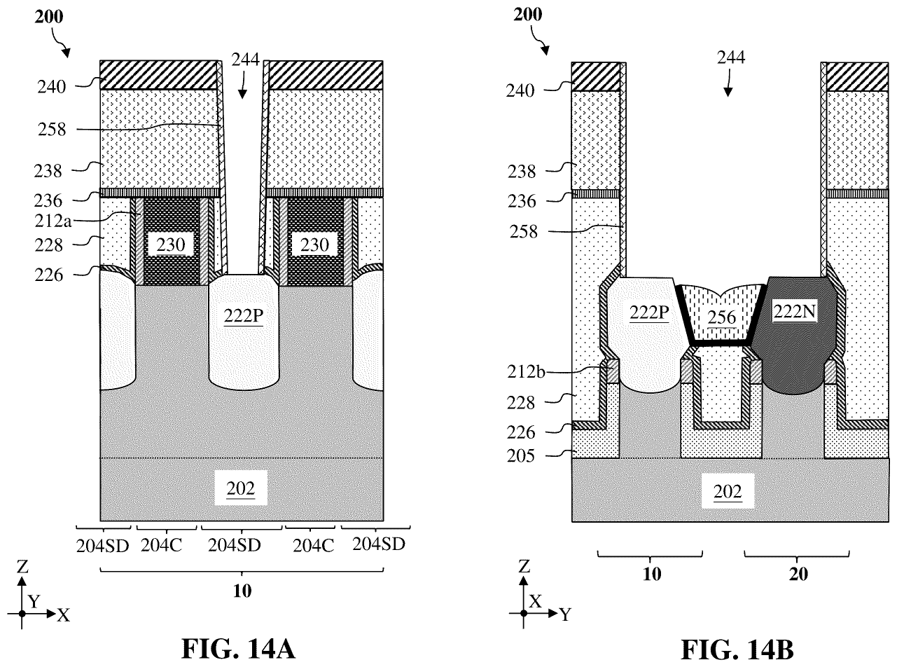

Referring now to FIGS. 1 and 14A-14B, method 100 includes a block 122 where a dielectric barrier layer 258 is formed in the upper portion 244U of opening 244. After the formation of the dielectric structure 256, in the present embodiments, to enhance isolation between the source/drain contact 262 (shown in FIGS. 16A-16B) and its adjacent gate structures 230, a dielectric barrier layer 258 is formed to extend along a sidewall surface of the upper portion 244U of opening 244. In an example process, a dielectric layer is conformally deposited over the structure 200 and in the opening 244 and is then etched back to only keep portions that extend along sidewall surface of the opening 244, thereby forming the dielectric barrier layer 258. In some embodiments, the dielectric barrier layer 258 may include silicon nitride, silicon oxide, or other suitable materials.

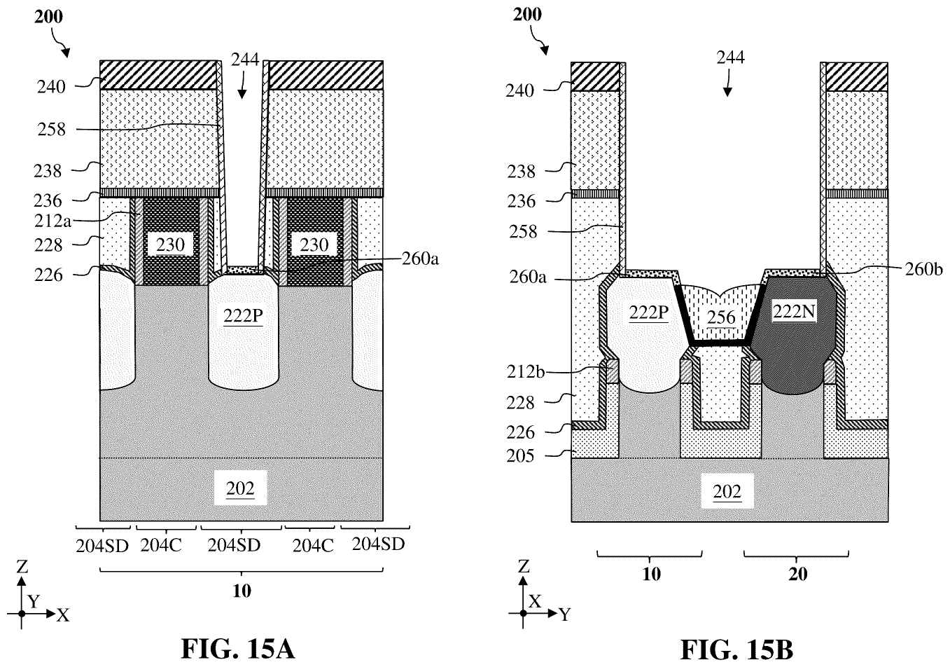

Referring now to FIGS. 1, 15A-15B and 16A-16B, method 100 includes a block 124 where silicide layers 260a-260b and a source/drain contact 262 are formed in the opening 244. With reference to FIGS. 15A-15B, after forming the dielectric barrier layer 258, silicide layers 260a-260b and source/drain contact 262 are formed in the opening 244. To form the silicide layers 260a-260b, a metal precursor (e.g., titanium, tantalum, nickel, cobalt, or tungsten) is deposited over the structure 200, including on the exposed surface of the n-type source/drain feature 222N and the exposed surface of the p-type source/drain feature 222P. An anneal process is then performed to bring about silicidation in the second region 20 and germinidation in the first region 10 between the metal precursor and the exposed semiconductor surfaces. In some embodiments, the unreacted metal precursor is selectively removed after the formation of the silicide layers 260a-260b. For embodiments in which the metal precursor includes nickel, nickel may react with silicon germanium in the p-type source/drain feature 222P to form the silicide layer 260a and may react with silicon in the n-type source/drain feature 222N to form the silicide layer 260b. Accordingly, the silicide layers 260a may include nickel silicide, nickel germanide, and nickel germanosilicide, and the silicide layer 260b may include nickel silicide. In this illustrated embodiment, the silicide layer 260a is in direct contact with top and sidewall surfaces of the source/drain feature 222P and one end of the dielectric liner 246 of the dielectric structure 256, and the silicide layer 260b is in direct contact with top and sidewall surfaces of the source/drain feature 222N and the other end of the dielectric liner 246 of the dielectric structure 256.

With reference to FIGS. 16A-16B, a conductive layer is then deposited over the structure 200, including in the opening 244 and on the dielectric structure 256 and silicide layers 260a-260b. The conductive layer may include aluminum (Al), copper (Cu), tungsten (W), cobalt (Co), ruthenium (Ru), or molybdenum (Mo) or other suitable materials and may be formed by any suitable deposition processes (e.g., CVD). A planarization process, such as a chemical mechanical polish (CMP) process, may be then performed to remove excess portions of the conductive layer to form the source/drain contact 262. Although not shown, in some embodiments, the source/drain contact 262 may further include a conductive barrier layer (e.g., TiN, TaN) extending along sidewall and bottom surfaces of the conductive layer. The source/drain contact 262 tracks the shape of the opening 244 that is partially filled by the dielectric structure 256, the dielectric barrier layer 258, and the silicide layers 260a-260b. That is, a bottom surface of the source/drain contact 262 has a profile substantially the same as that of the top surface 248s″ (shown in FIG. 13B).

The source/drain contact 262 includes an upper portion 262U over top surfaces of the silicide layers 260a-260b and a lower portion 262L disposed between the dielectric structure 256 and the upper portion 262U. The upper portion 262U resembles a rectangle, and the lower portion 262L resembles a trapezoid with a unique bottom surface (i.e., the top surface 248s″). The lower portion 262L is formed in and over the lower portion 244L of the opening 244 and is thus disposed laterally between the source/drain feature 222P and the source/drain feature 222N. The upper portion 262U has a height H1, and the lower portion 262L has a height H2. In an embodiment, a ratio of the height H2 to the height H1 is less than about 0.6. If the ratio is greater than 0.6, the lower portion 262L of the source/drain contact 262 may not be able to provide the benefit of reducing parasitic capacitance between the source/drain contact 262 and the adjacent source/drain features 222N and 222P. In some embodiments, the ratio of the height H2 to the height H1 is in a range between about 0.1 and about 0.6. In another embodiment, the height H2 is substantially equal to 0. That is, an entirety of the source/drain contact 262 is disposed over the S/D features 222P and 222N. In an embodiment, the height H2 may be in a range between about 2 nm and about 8 nm, and the height H1 may be in a range between about 10 nm and about 20 nm.

Referring to FIG. 1, method 100 includes a block 126 where further processes are performed. After forming the silicide layers 260a-260b and source/drain contact 262, further processes are performed to finalize the fabrication of the semiconductor structure 200. For example, additional features such as gate vias and interconnect structure(s) may be formed over and/or under the structure 200. In some embodiments, the interconnect structure may include multiple intermetal dielectric (IMD) layers and multiple metal lines or contact vias in each of the IMD layers. In some instances, the IMD layers and the first ILD layer 228 may share similar composition. The metal lines and contact vias in each IMD layer may be formed of metal, such as aluminum, tungsten, ruthenium, or copper. In some embodiments, the metal lines and contact vias may be lined by a barrier layer to prevent or reduce electro-migration.

In the above embodiments, the semiconductor structure 200 is implemented using FinFETs. In some other embodiments, the semiconductor structure 200 may be implemented using GAA transistors. For example, FIGS. 17A-17B illustrate an embodiment in which the fin-shaped active regions 204A-204B include channel layers 208, where the gate structures 230 engage with the channel layers 208 to form GAA transistors.

Although not intended to be limiting, one or more embodiments of the present disclosure provide many benefits to a semiconductor structure and the formation thereof. For example, a dielectric structure is formed to fill a lower portion of a source/drain contact opening such that the resultant source/drain contact would have a higher bottom surface. As such, parasitic capacitance between the source/drain contact and its adjacent source/drain features may be advantageously reduced, leading to improved device performance.

The present disclosure provides for many different embodiments. Semiconductor structures and methods of fabrication thereof are disclosed herein. In one exemplary aspect, the present disclosure is directed to a method. The method includes receiving a structure comprising a first source/drain feature over a source/drain region of a first fin-shaped active region protruding from a substrate, a second source/drain feature over a source/drain region of a second fin-shaped active region, an isolation feature disposed between the first fin-shaped active region and the second fin-shaped active region, and a multi-layer dielectric structure over the isolation feature and the first and second source/drain features. The method also includes forming an opening extending into the multi-layer dielectric structure, wherein a lower portion of the opening exposes sidewall surfaces of the first and second source/drain features, forming a dielectric feature in the lower portion of the opening, and forming a source/drain contact on the dielectric feature.

In some embodiments, the forming of the dielectric feature may include depositing a dielectric liner over the substrate and in the opening, forming a dielectric material layer over the dielectric liner, and performing an etching process to etch back the dielectric liner and the dielectric material layer. In some embodiments, the performing of the etching process may include implementing an etchant that etches the dielectric liner at a first etch rate and etches the dielectric material layer at a second etch rate different than the first etch rate. In some embodiments, the dielectric liner and the dielectric material layer may include silicon oxycarbonitride and have different nitrogen concentrations. In some embodiments, the dielectric material layer may be spaced apart from the first and second source/drain features by the dielectric liner. In some embodiments, a top surface of the dielectric feature spans a first width, a bottom surface of the dielectric feature spans a second width less than the first width. In some embodiments, the method may also include, after forming the dielectric feature, forming a silicide layer over the dielectric feature and in the opening. In some embodiments, the method may also include, after forming the dielectric feature, forming a dielectric barrier layer extending along a sidewall surface of the opening, wherein the source/drain contact is spaced apart from the multi-layer dielectric structure by the dielectric barrier layer. In some embodiments, the first source/drain feature is an n-type source/drain feature, and the second source/drain feature is a p-type source/drain feature.

In another exemplary aspect, the present disclosure is directed to a method. The method includes forming a dielectric structure over a substrate, the dielectric structure comprising a first portion disposed between a first source/drain feature and a second source/drain feature adjacent to the first source/drain feature, and a second portion over the first portion. The method also includes replacing a part of the first portion of the dielectric structure with a dielectric feature having a different composition than the dielectric structure, and replacing a part of the second portion of the dielectric structure with a source/drain contact electrically coupled to both the first and second source/drain features.

In some embodiments, the dielectric structure may include an etch stop layer conformally extending along top and sidewall surfaces of the first and second source/drain features and an interlayer dielectric layer on the etch stop layer. In some embodiments, the dielectric feature may include a dielectric fill layer and a dielectric liner extending along sidewall and bottom surfaces of the dielectric fill layer. In some embodiments, the dielectric fill layer may include silicon oxycarbide or silicon oxycarbonitride, and the dielectric liner may include silicon oxycarbide or silicon oxycarbonitride. In some embodiments, the replacing of the part of the first portion of the dielectric structure with the dielectric feature may include forming a patterned mask over the dielectric structure, removing the part of the first portion and the part of the second portion of the dielectric structure to form an opening exposing top and sidewall surfaces of the first and second source/drain features, and forming the dielectric feature in a lower portion of the opening. In some embodiments, the replacing of the part of the second portion of the dielectric structure with the source/drain contact may include after forming the opening and the dielectric feature, forming a dielectric barrier layer in the opening, forming a silicide layer over the first and second source/drain features, and forming the source/drain contact in the opening and over the dielectric feature. In some embodiments, a topmost surface of the dielectric feature is lower than a top surface of the first source/drain feature.

In yet another exemplary aspect, the present disclosure is directed to a semiconductor structure. The semiconductor structure includes a first transistor comprising a first gate structure over a first channel region and a first source/drain feature coupled to the first channel region, a second transistor comprising a second gate structure over a second channel region and a second source/drain feature coupled to the second channel region, a first dielectric structure extending from a lower portion of the first source/drain feature to a lower portion of the second source/drain feature, a second dielectric structure over the first dielectric structure and having a different composition than the first dielectric structure, and a source/drain contact electrically coupled to the first and second source/drain features and on the second dielectric structure.

In some embodiments, the semiconductor structure may also include a first silicide layer on the first source/drain feature and a second silicide layer on the second source/drain feature, where the second dielectric structure may include a first dielectric layer and a second dielectric layer over the first dielectric layer, and the first dielectric layer extends from the first silicide layer to the second silicide layer. In some embodiments, a bottommost surface of the source/drain contact may be lower than a topmost surface of the first source/drain feature. In some embodiments, the first channel region may include a plurality of nanostructures.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a structure comprising:
a first source/drain feature over a source/drain region of a first fin-shaped active region protruding from a substrate,
a second source/drain feature over a source/drain region of a second fin-shaped active region,
an isolation feature disposed between the first fin-shaped active region and the second fin-shaped active region, and
a multi-layer dielectric structure over the isolation feature and the first and second source/drain features;
forming an opening extending into the multi-layer dielectric structure, wherein a lower portion of the opening exposes sidewall surfaces of the first and second source/drain features;
forming a dielectric feature in the lower portion of the opening; and
forming a source/drain contact on the dielectric feature.

2. The method of claim 1, wherein the forming of the dielectric feature comprises:
depositing a dielectric liner over the substrate and in the opening;
forming a dielectric material layer over the dielectric liner; and
performing an etching process to etch back the dielectric liner and the dielectric material layer.

3. The method of claim 2, wherein the performing of the etching process includes implementing an etchant that etches the dielectric liner at a first etch rate and etches the dielectric material layer at a second etch rate different than the first etch rate.

4. The method of claim 2, wherein the dielectric liner and the dielectric material layer comprise silicon oxycarbonitride and have different nitrogen concentrations.

5. The method of claim 2, wherein the dielectric material layer is spaced apart from the first and second source/drain features by the dielectric liner.

6. The method of claim 1, wherein a top surface of the dielectric feature spans a first width, a bottom surface of the dielectric feature spans a second width less than the first width.

7. The method of claim 1, further comprising:
after forming the dielectric feature, forming a silicide layer over the dielectric feature and in the opening.

8. The method of claim 1, further comprising:
after forming the dielectric feature, forming a dielectric barrier layer extending along a sidewall surface of the opening, wherein the source/drain contact is spaced apart from the multi-layer dielectric structure by the dielectric barrier layer.

9. The method of claim 1, wherein the first source/drain feature is an n-type source/drain feature, and the second source/drain feature is a p-type source/drain feature.

10. A method, comprising:
forming a dielectric structure over a substrate, the dielectric structure comprising:
a first portion disposed between a first source/drain feature and a second source/drain feature adjacent to the first source/drain feature, and
a second portion over the first portion;
replacing a part of the first portion of the dielectric structure with a dielectric feature having a different composition than the dielectric structure; and
replacing a part of the second portion of the dielectric structure with a source/drain contact electrically coupled to both the first and second source/drain features.

11. The method of claim 10, wherein the dielectric structure comprises an etch stop layer conformally extending along top and sidewall surfaces of the first and second source/drain features and an interlayer dielectric layer on the etch stop layer.

12. The method of claim 10, wherein the dielectric feature comprises:
a dielectric fill layer; and
a dielectric liner extending along sidewall and bottom surfaces of the dielectric fill layer.

13. The method of claim 12, wherein the dielectric fill layer comprises silicon oxycarbide or silicon oxycarbonitride, and the dielectric liner comprises silicon oxycarbide or silicon oxycarbonitride.

14. The method of claim 10, wherein the replacing of the part of the first portion of the dielectric structure with the dielectric feature comprises:
forming a patterned mask over the dielectric structure;
removing the part of the first portion and the part of the second portion of the dielectric structure to form an opening exposing top and sidewall surfaces of the first and second source/drain features; and
forming the dielectric feature in a lower portion of the opening.

15. The method of claim 14, wherein the replacing of the part of the second portion of the dielectric structure with the source/drain contact comprises:
after forming the opening and the dielectric feature, forming a dielectric barrier layer in the opening;
forming a silicide layer over the first and second source/drain features; and
forming the source/drain contact in the opening and over the dielectric feature.

16. The method of claim 10, wherein a topmost surface of the dielectric feature is lower than a top surface of the first source/drain feature.

17. A semiconductor structure, comprising:
a first transistor comprising:
a first gate structure over a first channel region, and
a first source/drain feature coupled to the first channel region;
a second transistor comprising:
a second gate structure over a second channel region, and
a second source/drain feature coupled to the second channel region;
a first dielectric structure extending from a lower portion of the first source/drain feature to a lower portion of the second source/drain feature;
a second dielectric structure over the first dielectric structure and having a different composition than the first dielectric structure; and
a source/drain contact electrically coupled to the first and second source/drain features and on the second dielectric structure.

18. The semiconductor structure of claim 17, further comprising:
a first silicide layer on the first source/drain feature; and
a second silicide layer on the second source/drain feature,
wherein the second dielectric structure comprises a first dielectric layer and a second dielectric layer over the first dielectric layer, and the first dielectric layer extends from the first silicide layer to the second silicide layer.

19. The semiconductor structure of claim 17, wherein a bottommost surface of the source/drain contact is lower than a topmost surface of the first source/drain feature.

20. The semiconductor structure of claim 17, wherein the first channel region comprises a plurality of nanostructures.
